(19) United States
(12) Patent Application Publication
(10) Pub. No.: US 2012/0049194 A1
(43) Pub. Date: Mar. 1, 2012

(54) Increased Charge Carrier Mobility in Transistors by Providing a Strain-Inducing Threshold Adjusting Semiconductor Material in the Channel

(75) Inventors: Thilo SCHEIPER, Dresden (DE); Jan HOENTSCHEL, Dresden (DE)

(73) Assignee: GLOBALFOUNDRIES INC., Grand Cayman (KY)

(21) Appl. No.: 13/186,934

(22) Filed: Jul. 20, 2011

(30) Foreign Application Priority Data
Aug. 31, 2010 (DE) 10 2010 040 061.0

(51) Int. Cl. H01L 29/78; H01L 21/20

(52) U.S. Cl. 257/65; 438/478; 257/E29.255; 257/E21.09

(57) ABSTRACT

In complex semiconductor devices, high-k metal gate electrode structures may be provided in an early manufacturing stage, wherein the threshold voltage adjustment may be accomplished by forming two different semiconductor materials on the silicon base material. In this manner, superior strain conditions may be obtained in the channel region. For example, a thin silicon material may be formed on a silicon/germanium material that may substantially determine the resulting threshold voltage of the P-channel transistor.

### BACKGROUND OF THE INVENTION

1. Field of the Invention

Generally, the present disclosure relates to integrated circuits, and, more particularly, to transistors comprising a high-k metal gate electrode structure formed in an early manufacturing stage.

2. Description of the Related Art

The fabrication of complex integrated circuits requires the provision of a large number of transistors, which represent the dominant circuit elements in complex integrated circuits. For example, several hundred million transistors may be provided in presently available complex integrated circuits, wherein performance of the transistors in the speed critical signal paths substantially determines overall performance of the integrated circuit. Generally, a plurality of process technologies are currently practiced, wherein, for complex circuitry, such as microprocessors, storage chips and the like, CMOS technology is the most promising approach due to the superior characteristics in view of operating speed and/or power consumption and/or cost efficiency. In CMOS circuits, complementary transistors, i.e., P-channel transistors and N-channel transistors, are used for forming circuit elements, such as inverters and other logic gates to design highly complex circuit assemblies, such as CPUs, storage chips and the like. During the fabrication of complex integrated circuits using CMOS technology, the complementary transistors, i.e., N-channel transistors and P-channel transistors, are formed on a substrate including a crystalline semiconductor layer. A MOS transistor, or generally a field effect transistor, irrespective of whether an N-channel transistor or a P-channel transistor is considered, comprises so-called PN junctions that are formed by an interface positioned between highly doped drain and source regions and an inversely or weakly doped channel region disposed between the drain region and the source region. The conductivity of the channel region, i.e., the drive current capability of the conductive channel, is controlled by a gate electrode formed in the vicinity of the channel region and separated therefrom by a thin insulating layer. The conductivity of the channel region, upon formation of a conductive channel due to the application of an appropriate control voltage to the gate electrode, depends on, among other things, the mobility of the charge carriers and, for a given extension of the channel region in the transistor width direction, on the distance between the source and drain regions, which is also referred to as channel length. Thus, the reduction of the channel length, and associated therewith the reduction of the channel resistivity, is a dominant design criterion for accomplishing an increase in the operating speed of the integrated circuits.

When reducing the channel length of field effect transistors, generally an increased degree of capacitive coupling is required in order to maintain controllability of the channel region, which may typically require an adaptation of a thickness and/or material composition of the gate dielectric material. For example, for a gate length of approximately 80 nm, a gate dielectric material based on silicon dioxide with a thickness of less than 2 nm may be required in high-speed transistor elements, which may, however, result in increased leakage currents caused by hot carrier injection and direct tunneling of charge carriers through the extremely thin gate dielectric material. Since a further reduction in thickness of silicon dioxide-based gate dielectric materials may increasingly become incompatible with thermal power requirements of sophisticated integrated circuits, in some approaches, the inferior controllability of the channel region of the short channel transistors caused by the continuous reduction of the critical dimensions of gate electrode structures has been addressed by an appropriate adaptation of the material composition of the gate dielectric material.

To this end, it has been proposed that, for a physically appropriate thickness of a gate dielectric material, i.e., for a thickness resulting in an acceptable level of gate leakage currents, a desired high capacitive coupling may be achieved by using appropriate material systems, which have a significantly higher dielectric constant compared to the conventionally used silicon dioxide-based materials. For example, dielectric materials including hafnium, zirconium, aluminum and the like may have a significantly higher dielectric constant and are therefore referred to as high-k dielectric materials, which are to be understood as materials having a dielectric constant of 10.0 or higher when measured in accordance with typical measurement techniques. As is well known, the electronic characteristics of the transistors also strongly depend on the work function of the gate electrode material, which in turn influences the band structure of the semiconductor material in the channel regions separated from the gate electrode material by the gate dielectric layer. In well-established polysilicon/silicon dioxide-based gate electrode structures, the corresponding threshold voltage, that is strongly influenced by the gate dielectric material and the adjacent electrode material, is adjusted by appropriately doping the polysilicon material in order to appropriately adjust the work function of the polysilicon material at the interface between the gate dielectric material and the electrode material. Similarly, in gate electrode structures including a high-k gate dielectric material, the work function has to be appropriately adjusted for N-channel transistors and P-channel transistors, respectively, which may require appropriately selected work function adjusting metal species, such as lanthanum for N-channel transistors and aluminum for P-channel transistors and the like. For this reason, corresponding metal-containing conductive materials may be positioned close to the high-k gate dielectric material in order to form an appropriately designed interface that results in the target work function of the gate electrode structure. In some conventional approaches, the work function adjustment is performed at a very late manufacturing stage, i.e., after any high temperature processes, after which a placeholder material of the gate electrode structures, such as polysilicon, is replaced by an appropriate work function adjusting species in combination with an electrode metal, such as aluminum and the like. In this case, however, very complex patterning and deposition process sequences are required in the context of gate electrode structures having critical dimensions of 50 nm and significantly less, which may result in severe variations of the resulting transistor characteristics.

Therefore, other process strategies have been proposed in which the work function adjusting materials may be applied in an early manufacturing stage, i.e., upon forming the gate electrode structures, wherein the metal species may be thermally stabilized and encapsulated in order to obtain the desired work function and thus threshold voltage of the transistors without being unduly influenced by the further processing. It turns out that, for any appropriate metal species and metal-containing electrode materials, an appropriate adaptation of the band gap of the channel semiconductor material may be required, for instance, in the P-channel transistors, in order to appropriately set the work function thereof. For this reason, frequently a so-called threshold adjusting semiconductor material, for instance in the form of a silicon/germanium mixture, is formed on the active regions of the P-channel transistors prior to forming the gate electrode structures, thereby obtaining the desired offset in the band gap of the channel semiconductor material.

The threshold adjusting semiconductor material is typically formed selectively on the silicon-based active region of the P-channel transistors while masking the active region of the N-channel transistors by an appropriate mask material, such as silicon dioxide, silicon nitride and the like. In a selective epitaxial growth process, the process parameters, such as temperature, gas flow rates and the like, are established in such a manner that a significant material deposition may be restricted to crystalline surface areas, thereby forming increasingly a silicon/germanium mixture on the silicon base material, wherein a germanium concentration, the germanium gradient in the growth direction and the finally obtained thickness in the silicon/germanium layer may thus determine the finally obtained threshold voltage for otherwise given transistor parameters. Thereafter, the gate electrode structures are formed by using high-k dielectric materials in combination with appropriate metal-containing cap layers and work function adjusting metal species, which may be incorporated into the high-k material and/or the metal-containing cap layers in order to obtain appropriate work functions and thus threshold voltages for the P-channel transistors and the N-channel transistors, respectively. In this manner, sophisticated high-k metal gate electrode structures may be provided in an early manufacturing stage, thereby avoiding a complex process strategy as required by the so-called replacement gate approach.

It is well known that, in view of enhancing overall performance of sophisticated transistors, also various strain engineering techniques are typically applied, since creating a specific type of strain in the channel region of silicon-based transistors may result in a significant increase of the charge carrier mobility, which in turn translates into superior current drive capability and thus switching speed. A plurality of strategies have thus been developed, for instance providing highly stressed layers above the completed transistor structures, providing strain-inducing sidewall spacer structures, embedding strain-inducing semiconductor alloys, such as silicon/germanium, silicon/carbon and the like, into drain and source areas of the transistors, while in other approaches, in addition to or alternatively, also globally strained semiconductor base materials may be used. Consequently, a plurality of process modules are typically applied separately from each other in order to enhance the overall performance of the transistors. For example, the process module for implementing the threshold adjusting silicon/germanium mixture into the channel region of the P-channel transistor may be applied in view of appropriately adjusting the threshold voltage of the transistor without taking into consideration any other transistor parameters. Furthermore, crystal defects have been observed in sophisticated P-channel transistors which are believed to be caused by the implementation of the threshold adjusting silicon/germanium material, as will be explained with reference to FIGS. 1a-1c.

FIG. 1a schematically illustrates a cross-sectional view of a semiconductor device 100 in which a silicon/germanium material is to be provided in the channel area of P-channel transistors on the basis of an epitaxial growth process. In the manufacturing stage shown, the device 100 comprises a substrate 101 and a silicon-based semiconductor layer 102. The substrate 101 and the silicon-based semiconductor layer 102 form a bulk configuration or a silicon-on-insulator (SOI) configuration, depending on the desired transistor architecture. For example, when an SOI configuration is considered appropriate, a buried insulating layer (not shown) is formed below the semiconductor layer 102 and thus separates the layer 102 from the substrate 101. The semiconductor layer 102 further comprises isolation structures 102C, such as shallow trench isolations, which laterally delineate semiconductor regions or active regions, such as active regions 102A, 102B. In the example shown, the active region 102A corresponds to the semiconductor region of a P-channel transistor, while the active region 102B corresponds to an N-channel transistor. A mask layer 103, such as a silicon dioxide material, a silicon nitride material and the like, is formed on the active region 102B in order to act as a deposition mask for the selective epitaxial growth process for forming a silicon/germanium material in the active region 102A. In some approaches, a recess 102R may be provided in the region 102A prior to actually depositing the silicon/germanium material.

The semiconductor device 100 as illustrated in FIG. 1a may be formed on the basis of the following processes. The isolation structure 102C is formed by using sophisticated lithography, etch, deposition and planarization techniques, wherein, prior to or after forming the isolation structure 102C, appropriate well dopant species may be incorporated into the active regions 102A, 102B in order to define the basic transistor characteristics. To this end, well-established implantation techniques and masking regimes may be applied. Thereafter, the mask 103 is formed, for instance, by oxidation, deposition and the like, and a portion of the mask material is removed from above the active region 102A, for instance by applying a resist mask and performing an etch process. If required, the recess 102R may be formed with any appropriate depth in order to adjust the finally obtained surface topography after the deposition of the silicon/germanium material. Next, a selective epitaxial growth process is performed after any cleaning processes and the like, wherein process parameters are selected such that a significant semiconductor material deposition is substantially restricted to exposed surface areas of the active region 102A, while any pronounced deposition on dielectric surface areas, such as the mask 103 and the isolation structure 102C, is suppressed. To this end, well-established chemical vapor deposition (CVD) techniques with process temperatures in the range of 650-750° C. have been developed with appropriately selected gas flow rates and process pressures, wherein the fraction of germanium in the silicon/germanium mixture is set on the basis of controlling the corresponding gas flow rates for otherwise given process conditions. As previously explained, the resulting electronic characteristics, in particular the resulting threshold voltage, may significantly depend on the thickness of the silicon/germanium material and the material composition, i.e., the germanium fraction contained therein and the corresponding germanium gradient. For example, a thickness of approximately 8-12 nm and a maximum germanium content of up to 25 atomic percent may be used in order to obtain the required threshold voltage.

FIG. 1b schematically illustrates the semiconductor device 100 in a further advanced manufacturing stage in which a silicon/germanium mixture or alloy 104 is formed in the active region 102A and thus represents a portion thereof, thereby providing the desired band gap offset, as discussed above. Moreover, a gate electrode structure 160A of a P-channel transistor 150A is formed on the channel material 104 and comprises a gate dielectric material 163A and a metal-containing electrode material 162A, followed by a further electrode material 161, such as silicon and the like. The materials 163A, 162A and 161 are encapsulated or confined by a spacer structure 165, for instance provided in the form of a silicon nitride material and the like, while a cap layer 164 reliably covers the electrode material 161. Similarly, a gate electrode structure 160B of an N-channel transistor 150B is formed on the active region 102B and may have basically a similar configuration as the gate electrode structure 160A. That is, a gate dielectric material 163B in combination with a metal-containing electrode material 162B and the electrode material 161 are provided in combination with the spacer structure 165 and the dielectric cap layer 164. It should be noted that the gate dielectric materials 163A, 163B may have basically the same configuration and may differ in a work function adjusting species that may have been incorporated therein during the previous processing. For example, frequently appropriate species may be diffused in to the gate dielectric material in order to modify the characteristics thereof in view of achieving a desired overall work function and thus threshold voltage. As discussed above, the gate dielectric layers 163A, 163B comprise a high-k dielectric material, such as hafnium oxide and the like, possibly in combination with a thin dielectric material, for instance in the form of silicon oxynitride and the like, in view of superior interface characteristics. The metal-containing electrode materials 162A, 162B may have substantially the same composition or may differ with respect to a work function adjusting species, depending on the process strategy applied for forming the gate electrode structures 160A, 160B.

A typical process flow for forming the semiconductor device 100 as shown in FIG. 1b may comprise the following processes. The basic material composition of the gate dielectric layers 163A, 163B is provided, possibly in combination with any work function adjusting metal species and additional cap materials, such as titanium nitride and the like, and an appropriate treatment, such as anneal processes and the like, may be applied in order to adjust the overall characteristics of the gate dielectric materials 163A, 163B. Subsequently the same or different materials are deposited for the layers 162A, 162B, followed by the deposition of the material 161, for instance in the form of amorphous silicon. Moreover, any further material, such as the cap material 164, is provided and the resulting layer stack is patterned by using sophisticated lithography and etch techniques. Next, the spacer structure 165 is formed by any appropriate deposition and etch strategy in order to reliably confine, in particular, the sensitive materials 163A, 163B and 162A, 162B.

When applying the above-described process sequence, however, crystal defects have been observed in the material 104, as indicated by 104A, when using a thickness and material composition as specified above. These defects in the channel region of the transistor 150A may result in a significant variation of transistor characteristics or may even result in a non-acceptable transistor performance.

FIG. 1c schematically illustrates the semiconductor device 100 in a further advanced manufacturing stage. As shown, the transistor 150A comprises the gate electrode structure 160A with an additional spacer structure 166, which may include the spacer structure 165 (FIG. 1b). On the basis of the spacer structure 166, drain and source regions 152 may be formed in the active regions 102A, 102B in order to complete the basic transistor configuration. It should be appreciated that frequently additional mechanisms may be implemented in order to increase performance of the transistors 150A and/or 150B. For example, a silicon/germanium material may be incorporated into the drain and source areas after forming the gate electrode structure 160A, wherein the silicon/germanium material may be formed in a strained state due to the difference in the natural lattice constants between a relaxed silicon/germanium mixture and a silicon material. That is, silicon/germanium material has a greater lattice constant and, when grown on a silicon base material so as to adopt the silicon lattice constant, a compressively strained state is created in the silicon/germanium material, which in turn may mechanically act on the channel region 151, thereby also inducing a compressive strain component along the current flow direction in the transistor 150A. Similarly, strain-inducing mechanisms may be implemented in the transistor 150B, if required.

Generally, the approach of forming sophisticated high-k metal gate electrode structures on the basis of a threshold adjusting semiconductor material is a promising approach, wherein, however, the presence of certain lattice defects may contribute to reduced transistor performance, while also any performance enhancing possibilities in providing a dedicated channel material are not taken into account in the conventional process strategy.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides semiconductor devices and manufacturing techniques in which the electronic characteristics of a channel region of a transistor receiving a sophisticated high-k metal gate electrode structure may be adjusted by using a semiconductor material having a different natural lattice constant compared to the semiconductor base material. Furthermore, at least one further semiconductor material may be used which may have a different natural lattice constant compared to the previously provided threshold adjusting semiconductor material in order to achieve superior strain conditions in the channel region, thereby enabling an efficient overall adjustment of the threshold voltage and also increasing charge carrier mobility in the channel region.

One illustrative method disclosed herein relates to forming a transistor. The method comprises forming a threshold adjusting semiconductor material having a first natural lattice constant on a semiconductor base material that has a second natural lattice constant, wherein the first natural lattice constant is different from the second natural lattice constant. The method further comprises forming a crystalline cap material on the threshold adjusting semiconductor material, wherein the crystalline cap material has a third natural lattice constant that differs from the first natural lattice constant. Moreover, the method comprises forming a gate electrode structure on the crystalline cap material, wherein the gate electrode structure comprises a gate insulation layer comprising a high-k dielectric material.

A further illustrative method disclosed herein relates to forming a semiconductor device. The method comprises forming a first crystalline semiconductor material on a semiconductor base material of a first active region, while covering a second active region, wherein the first crystalline semiconductor material and the semiconductor base material have different natural lattice constants. The method further comprises forming a second crystalline semiconductor material on the first crystalline semiconductor material, wherein a natural lattice constant of the second crystalline semiconductor material differs from the natural lattice constant of the first crystalline semiconductor material. Moreover, the method comprises forming a first gate electrode structure on the second crystalline semiconductor material and a second gate electrode structure on the second active region, wherein the first and second gate electrode structures comprise a gate insulation layer containing a high-k dielectric material.

One illustrative semiconductor device disclosed herein comprises a drain region and a source region that are formed in an active region of a transistor. The semiconductor device further comprises a channel region formed laterally between the drain region and the source region and comprising a semiconductor base material, a strain-inducing first semiconductor material formed on the semiconductor base material and a strained second semiconductor material formed on the strain-inducing first semiconductor material. The semiconductor device further comprises a gate electrode structure formed on the strained second semiconductor material and comprising a high-k dielectric material, a metal-containing cap layer formed above the high-k dielectric material and a semiconductor electrode material that is formed above the metal-containing cap layer.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1c schematically illustrate cross-sectional views of a semiconductor device during various manufacturing stages in forming sophisticated high-k metal gate electrode structures on the basis of a threshold adjusting semiconductor material, according to conventional strategies;

FIG. 2a schematically illustrates a cross-sectional view of the semiconductor device during a selective epitaxial growth process for providing a threshold adjusting semiconductor material in combination with a crystalline cap material with natural lattice constants in order to adjust the threshold voltage and provide superior strain conditions in the channel region of a transistor, according to illustrative embodiments;

FIG. 2b schematically illustrate a top view of the device of FIG. 2a, thereby indicating the strain conditions in the active region, according to illustrative embodiments;

FIG. 2c schematically illustrates the semiconductor device during a selective epitaxial growth process in which the crystalline cap material may be provided as a semiconductor alloy having a reduced natural lattice constant, according to illustrative embodiments;

FIG. 2d schematically illustrates the semiconductor device during a selective epitaxial growth process in which a carbon species may be incorporated into a silicon/germanium mixture in order to enhance the crystal quality, according to illustrative embodiments; and

FIGS. 2e-2g schematically illustrate cross-sectional views of the semiconductor device in various advanced manufacturing stages in forming sophisticated transistors including a high-k metal gate electrode structure, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally provides semiconductor devices and manufacturing techniques in which an efficient threshold adjustment may be obtained on the basis of two different semiconductor materials, i.e., a threshold adjusting semiconductor material and a crystalline cap material, which may differ in their material composition and thus in their natural lattice constants. In this manner, in addition to appropriate threshold voltages for transistors comprising high-k metal gate electrode structures, superior strain conditions and/or reduced lattice defects may be provided in the channel region, thereby further enhancing overall transistor performance and/or increasing production yield. As previously discussed, strain engineering represents a very efficient process technique for increasing performance of transistors by increasing the charge carrier mobility in the channel region. For example, upon forming a silicon/germanium material, which has a greater natural lattice constant compared to silicon material, on a silicon base material, the silicon/germanium material may adopt the lattice constant of the silicon, thereby forming a strained lattice. When forming a relatively thin silicon/germanium material, for instance on the active region of a P-channel transistor, the resulting strain may be less pronounced due to any edge effects and the reduced thickness of the silicon/germanium material. Furthermore, in some illustrative embodiments disclosed herein, the germanium concentration may be varied so as to increase with increasing deposition time, thereby providing a moderately “relaxed” silicon/germanium surface, which may thus act as a “base material” for the deposition of the crystalline cap material, which may be provided as a material having a different natural lattice constant with respect to the underlying semiconductor material, thereby also growing in a strained state. The crystalline cap material may be provided with a reduced layer thickness compared to the underlying semiconductor material, which may also be referred to as a threshold adjusting semiconductor material and which may thus represent a strain-inducing semiconductor material for the crystalline cap material. Consequently, by selecting appropriate material compositions and adjusting the deposition parameters, an efficient overall adjustment of the electronic characteristics, i.e., the band gap of the channel material, may be accomplished, while at the same time adjusting the strain conditions at least within a thin surface layer of the resulting channel region.

In some illustrative embodiments disclosed herein, the actual threshold adjusting semiconductor material may be provided in the form of a silicon/germanium material, possibly with a varying germanium concentration, wherein, in some embodiments, additionally a carbon species may be incorporated at any appropriate phase of the deposition process in order to further enhance the crystal quality of the resulting material layer. On the other hand, the crystalline cap layer may be provided in the form of a silicon material, which may thus provide superior charge carrier mobility due to its strained state, while, in still other illustrative embodiments, an additional species, such as carbon, may be implemented into the crystalline cap material, for instance by providing a silicon/carbon mixture, thereby even further increasing the resulting strain in the crystalline cap material. The various crystalline materials of different natural lattice constant may, in some illustrative embodiments, be formed during a single selective epitaxial growth process by appropriately adjusting the gas flow rates of the precursor gases, thereby essentially providing a high degree of compatibility with conventional process flows, as described above, since the additional process steps may be avoided. It should be appreciated that a deposition process performed in the same process chamber during a common deposition sequence for forming different materials without intermittently exposing the device to the ambient atmosphere may also be indicated herein as an in situ process. It should be appreciated that the term “in situ” process may also include any processes in which different deposition chambers may be used, for instance on the basis of a cluster tool, wherein, however, any transport activities between the different process chambers may be accomplished without exposing the substrate to the ambient atmosphere.

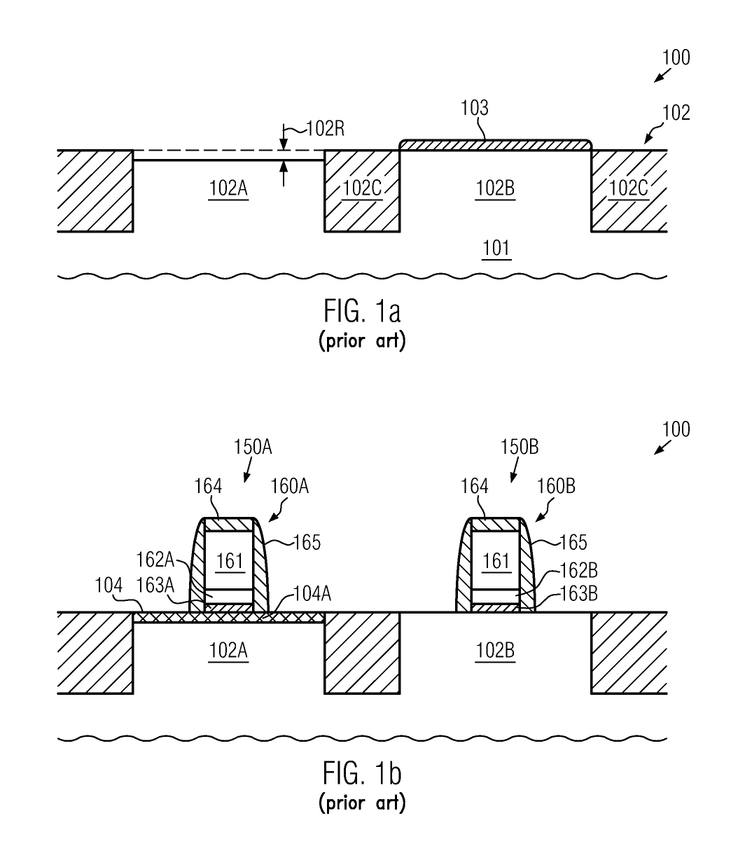

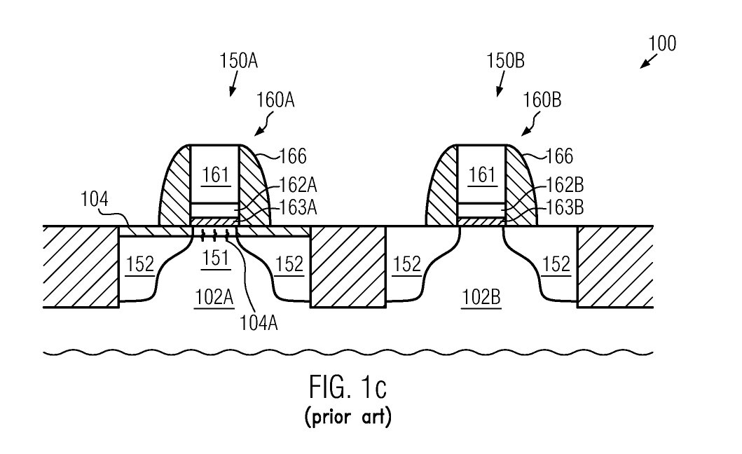

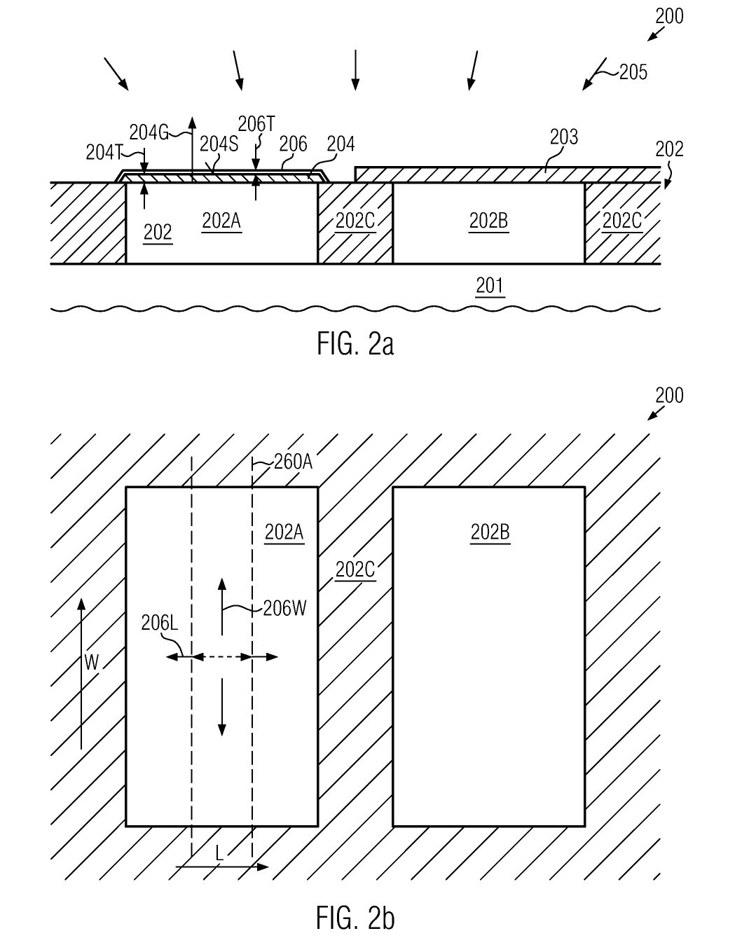

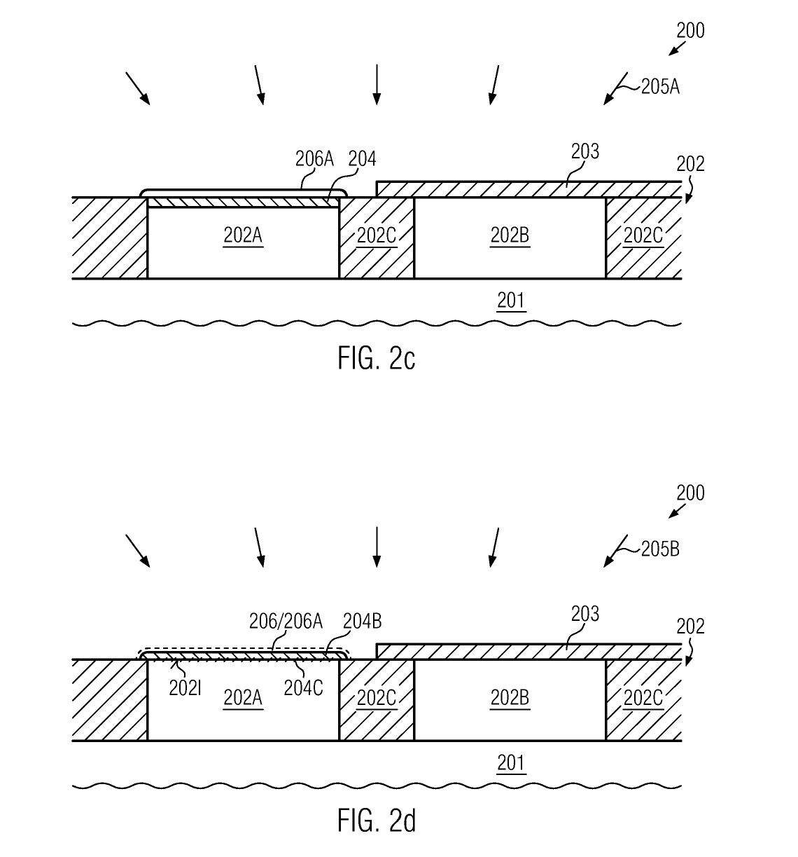

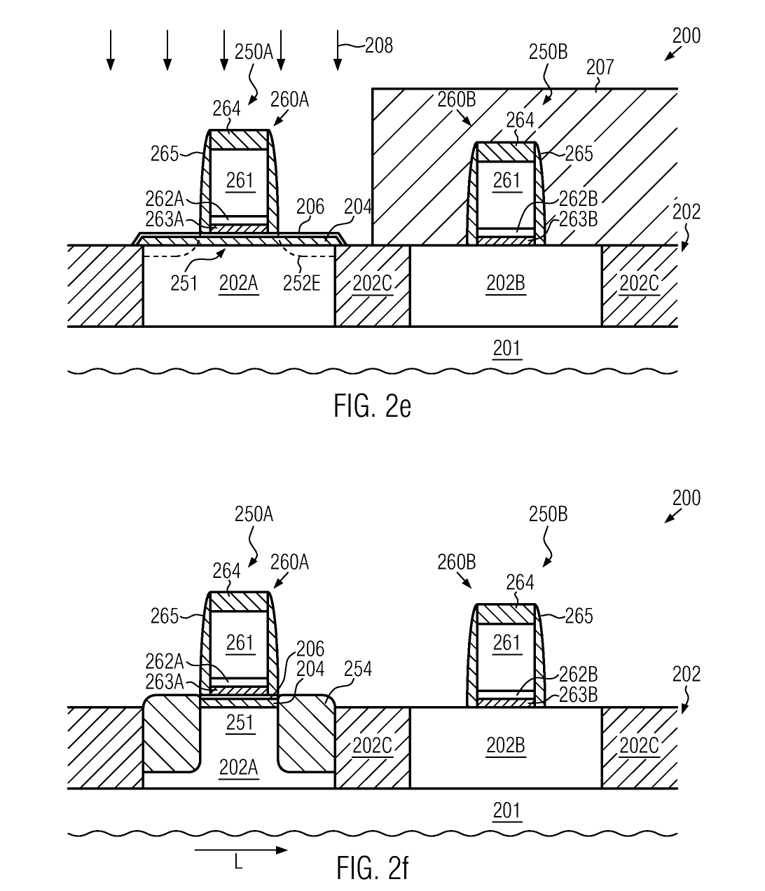

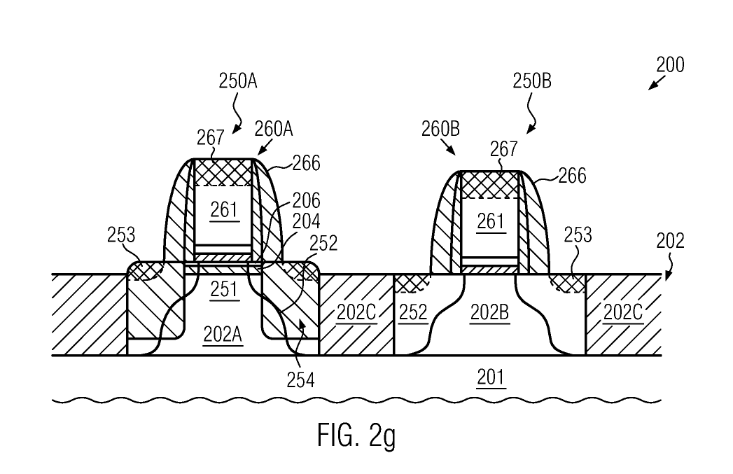

With reference to FIGS. 2a-2g, further illustrative embodiments will now be described in more detail, wherein reference may also be made to FIGS. 1a-1c, if appropriate.

FIG. 2a schematically illustrates a cross-sectional views of the semiconductor device 200 comprising a substrate 201 and a semiconductor layer 202. The semiconductor layer 202 may comprise active regions 202A, 202B, which may be laterally delineated by an isolation region 202C. With respect to any characteristics of the substrate 201 and the semiconductor layer 202, the same criteria may apply as previously explained with reference to the semiconductor device 100. Furthermore, in the embodiment shown, the active region 202A may correspond to the active region of a P-channel transistor still to be formed. On the other hand, the active region 202B may correspond to an N-channel transistor still to be formed, wherein, however, a different configuration may also be contemplated in the present application if one type of transistor may require a corresponding adaptation of the threshold voltage on the basis of a semiconductor material. Furthermore, as shown, the active region 202B may be covered by a mask 203, which may act as a deposition mask during a selective epitaxial growth process 205. The active region 202A may comprise the base material of the semiconductor layer 202 which may be provided in the form of a silicon-based material, i.e., the semiconductor layer 202 may comprise silicon material, possibly in combination with additional components, such as carbon, germanium and the like, however, at a significantly reduced fraction compared to the silicon contents of the semiconductor layer 202. Moreover, in the manufacturing stage shown, the active region 202A may comprise a first semiconductor material 204, which may also be referred to as a strain-inducing semiconductor material or as a threshold adjusting semiconductor material, since the material 204 may significantly affect the electronic characteristics of a channel region to be defined in the active region 202A. The semiconductor material 204 may have any appropriate material composition with respect to adjusting a desired overall band gap configuration at the surface of the active region 202A and may, in some illustrative embodiments, comprise silicon and germanium. The layer 204 may be provided with a thickness of approximately 8-15 nm, while a germanium concentration, for instance a maximum germanium concentration, may be selected to be approximately 25 atomic percent, while, however, it should be appreciated that any other maximum concentration values may be selected, depending on the required electronic behavior in the active region 202A. Moreover, in some illustrative embodiments, the germanium concentration may vary, as indicated by a concentration gradient 204G, wherein the concentration may increase starting from the base material 202 of the active region 202A. In this manner, the overall number of lattice defects within the layer 204 may be reduced. For example, the gradient 204G may be obtained by providing an initial germanium concentration of approximately 5 atomic percent and increasing the concentration to approximately 30 atomic percent or higher, depending on the overall device requirements. It should be appreciated, however, that any other variation of the germanium concentration may be applied. As will be described later on in more detail, in some embodiments, an additional atomic species, such as carbon, may be implemented in order to further enhance overall performance of the device 200.

Moreover, a second crystalline semiconductor material, which may also be indicated as a crystalline cap material 206, may be formed on the semiconductor layer 204 and may have a different natural lattice constant compared to the semiconductor layer 204. As previously explained, the layer 204 may be provided at least with a certain degree of “relaxation” so that a silicon-based material may be efficiently used for forming the layer 206, which may thus be grown in a strained state due to the mismatch between the natural lattice constants of the materials 206 and 204. The layer 206 may be provided with a thickness 206T, which may be less than a thickness 204T of the material layer 204 so that generally the material 204 may have a significant influence on the resulting electronic characteristics, i.e., the band gap configuration of the active region 202A in the vicinity of a gate dielectric material still to be formed. For example, the layer thickness 206T may be adjusted to approximately 5 nm or less.

The semiconductor device 200 as shown in FIG. 2a may be formed on the basis of the following processes. The active regions 202A, 202B and the isolation structure 202C may be formed in accordance with any appropriate process strategy, as is, for instance, also described above with reference to the semiconductor device 100. Similarly, the deposition mask 203 may be formed by oxidation, deposition and the like, as described above. If required, a recess (not shown) may be formed in the active region 202A in view of surface topography and the like, as is also previously explained with reference to the semiconductor device 100. Thereafter, the device 200 may be prepared for the selective epitaxial growth process 205 in which appropriate process parameters may be applied in order to form the layer 204 having the desired composition, for instance with a varying gradient, such as the gradient 204G, if considered appropriate. After a certain phase of the deposition process 205, at least one process parameter, such as the supply of precursor gases, may be changed in order to form the cap layer 206 immediately on the layer 204. To this end, in some illustrative embodiments, the supply of a precursor gas containing a germanium species may be discontinued or at least may be significantly reduced in order to form the material layer 206 having a different natural lattice constant compared to the material 204, at least at a surface 204S thereof. For example, the layer 206 may be provided in the form of a silicon material, while, in other cases, a reduced concentration of germanium may still be present, while still in other cases a different atomic species may be incorporated, as will be described later on in more detail.

Appropriate values for the composition, thickness and the process parameters of the process 205 may be readily determined on the basis of experiments in which the electronic characteristics and the strain conditions may be monitored for different settings. For example, the finally obtained performance of a transistor formed on the basis of the active region 202A may be used as an efficient test parameter in order to evaluate the efficiency of various parameter settings and thus of various layer thickness values and material compositions for the materials 204, 206.

FIG. 2b schematically illustrates a top view of the semiconductor device 200 after forming the material layers 204 and 206 on the base material of the active region 202A. In the embodiment shown, the layer 204 (FIG. 2a) may result in a strained state of the layer 206 (FIG. 2a) if the natural lattice constant of the layer 206 is less than the natural lattice constant of the layer 204, which may exhibit, at least at the surface thereof, a more or less relaxed state. Consequently, in this case, the layer 206 may have a bi-axial tensile strain, which, however, may have a different size in a length direction, indicated as L, and a width direction, indicated as W. That is, due to the rectangular configuration of the active region 202A, typically a strain component 206W in the width direction may be greater than the corresponding strain 206L along the length direction. Furthermore, the corresponding strain conditions may be even further modified upon forming a gate electrode structure, which is schematically indicated by the dashed lines 260A, since any processing after providing the gate electrode structure 260A may result in a more or less pronounced relaxation of the strain in the layer 206, which may thus even further reduce the strain in the length direction, while the strain component 206W may not be substantially affected by a corresponding relaxation mechanism. In this case, the tensile strain component 206W may efficiently increase the mobility of holes in the layer 206, while a corresponding tensile strain component, which would result in a degradation of the mobility of holes along the length direction and thus current flow direction, is significantly reduced. Consequently, in total, enhanced charge carrier mobility may be obtained on the basis of the strained layer 206.

FIG. 2c schematically illustrates the semiconductor device 200 during a selective deposition process 205A according to further illustrative embodiments. As illustrated, during the deposition process 205A, the first semiconductor layer 204 may be provided, for instance, in the form of a silicon/germanium material with appropriate thickness and material composition, possibly in combination with a germanium concentration gradient, and thereafter the process parameters may be changed so as to deposit a layer 206A as a crystalline cap material having a different natural lattice constant compared to the layer 204, as is also previously described. During the process 205A, carbon species may be incorporated into the layer 206A, thereby providing a silicon/carbon alloy, which has a reduced lattice constant compared to a pure silicon material. In this manner, the strain conditions as discussed above with reference to FIG. 2b may be even further enhanced since the corresponding tensile strain component along the width direction, i.e., the direction perpendicular to the drawing plane of FIG. 2c, may be even further increased, however, without significantly affecting the overall characteristics of the layers 204, 206A, since a moderately low carbon content may be incorporated. For example, one to several atomic percent of carbon material may be implemented into the semiconductor material 206A.

FIG. 2d schematically illustrates the semiconductor device 200 during a selective epitaxial growth process 205B, in which a layer 204B may be formed on the base material of the active region 202A. For example, a silicon/germanium alloy may be formed during the process 205B, wherein, at least in an initial phase of the deposition process 205B, a carbon species 204C may be incorporated into the layer 204B. In this case, the carbon species 204C is at least present at an interface 2021 formed between the base material 202 and the layer 204B. In this manner, the number of lattice defects may be reduced upon forming a silicon/germanium-containing material layer on the silicon base material 202. Thereafter, the process parameters of the process 205B may be changed so as to form the layer 206 or the layer 206A with a desired material composition and mismatch in lattice constant, as discussed above.

FIG. 2e schematically illustrates the semiconductor device 200 in a further advanced manufacturing stage according to illustrative embodiments. As illustrated, a gate electrode structure 260A of a transistor 250A may be formed on the active region 202A, i.e., on the crystalline cap layer 206 having the strained state, as described above. The gate electrode structure 260A may comprise a gate dielectric material 263A including a high-k material, followed by a metal-containing cap material 262A and a semiconductor-based electrode material 261. Moreover, a sidewall spacer structure 265 and a dielectric cap layer or layer system 264 may provide for the integrity of the materials 261, 262A, 263A.

Similarly the gate electrode structure 260B of a transistor 250B may be formed on the active region 202B and may comprise a gate dielectric material 263B in combination with a metal-containing electrode material 262B. Furthermore, the components 261, 265 and 264 may also be provided in the gate electrode structure 260B. As discussed above with reference to the semiconductor device 100, the materials 263A, 262A in combination with the crystalline cap material and the threshold adjusting semiconductor material 204 may provide a desired threshold voltage of the transistor 250A. On the other hand, the materials 263B and 262B may result in an appropriate threshold voltage for the transistor 250B. With respect to any process strategies for forming the gate electrode structures 260A, 260B, it may be referred to the discussion above with reference to the semiconductor device 100. It should be appreciated that, in some illustrative embodiments, the transistor 250A may represent a P-channel transistor and the threshold adjusting semiconductor material 204 may comprise silicon and germanium, as is also explained above. On the other hand, the transistor 250B may represent an N-channel transistor.

Moreover, the processing may be continued by providing an implantation mask 207 for covering the transistor 250B, while the transistor 250A may be exposed to an ion implantation sequence 208 during which, among others, drain and source dopant species may be incorporated so as to form drain and source extension regions 252E in the active region 202A laterally adjacent to the gate electrode structure 260A. During the implantation sequence 208, a certain degree of stress relaxation may occur in the layer 206 and also in the layer 204, if a certain strained component has been preserved therein. Thus, any longitudinal strain component may be significantly reduced, as previously discussed with reference to FIG. 2b, while a width component may still be preserved without significant modification. Consequently, in a channel region 251 positioned within the materials 204 and 206 below the gate electrode structure 260A, a significant strain may still exist, thereby providing superior charge carrier mobility, as discussed above.

FIG. 2f schematically illustrates the semiconductor device 200 according to further illustrative embodiments in which an additional performance enhancing mechanism may be implemented in the transistor 250A. As illustrated, a strained semiconductor material 254, such as a silicon/germanium material, may be incorporated into the active region 202A, thereby also exerting a strain in the channel region 251 in the form of a substantially uniaxial strain acting along the length direction L. In this manner, a desired compressive strain component may be obtained along the current flow direction in the channel region 251, while, at the same time, the superior strain condition of the layer 206, as discussed above, may further enhance overall performance of the transistor 250A. The strained semiconductor material 254 may be incorporated on the basis of well-established process techniques, for instance by forming corresponding cavities in the active region 202A, thereby also reducing the non-desired strain component in the length direction of the layer 206, as discussed above with reference to FIG. 2b, since exposed areas of the layers 204 and 206 are removed during the formation of the corresponding cavities. Thereafter, the material 254 may be grown in a strained state by applying well-established selective epitaxial growth techniques. During the formation of the material 254, the transistor 250B may be covered by any appropriate mask layer (not shown).

Based on the configuration as shown in FIG. 2f, the further processing may be continued by forming drain and source regions, for instance including extension regions, as previously explained with reference to FIG. 2e.

FIG. 2g schematically illustrates the semiconductor device 200 in a further advanced manufacturing stage. As shown, drain and source regions 252 may be provided in the active regions 202A, 202B, which may be accomplished by using a sidewall spacer structure 266 for defining the vertical and lateral dopant profile. Moreover, in the embodiment shown, the strained semiconductor material 254 may be incorporated into the active region 202A, as previously discussed with reference to FIG. 2f, while, in other illustrative embodiments, the material 254 may be omitted, depending on the overall process and device requirements. Furthermore, in some illustrative embodiments, a metal silicide 253 may be formed within the drain and source regions 252 and a metal silicide 267 may also be formed within the electrode material 261.

Typically, the device 200 as illustrated in FIG. 2g may be formed on the basis of any appropriate process strategy, i.e., a corresponding sequence of implantation processes may be performed in accordance with an associated masking regime so as to introduce the required drain and source dopant species for the transistors 250A and 250B, respectively. To this end, the spacer structure 266 may be used as an appropriate implantation mask. After performing any high temperature processes in order to re-crystallize implantation-induced damage and activate the dopant species, the metal silicide materials 253 and 267 may be formed on the basis of well-established silicidation techniques. To this end, any dielectric cap materials may be removed at any appropriate manufacturing stage in order to expose the electrode material 261.

Consequently, the channel region 251 of the transistor 250A comprises the semiconductor materials 204 and the strained material 206, thereby providing superior strain conditions and the desired band gap configuration, as discussed above. In some illustrative embodiments, also the number of lattice defects in the materials 204 and 206 may be reduced due to the presence of a certain amount of carbon species at and within the semiconductor layer 204.

As a result, the present disclosure provides manufacturing techniques and semiconductor devices in which the band gap configuration of a transistor, such as a P-channel transistor, may be adjusted on the basis of semiconductor materials having different natural lattice constants in order to provide superior strain conditions in the resulting channel region. For example, a silicon material or a silicon/carbon material may be formed on a silicon and germanium-comprising material. The semiconductor materials of different natural lattice constant may be provided in a single deposition process, thereby avoiding additional process complexity compared to conventional process strategies.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a transistor, the method comprising:
forming a threshold adjusting semiconductor material having a first natural lattice constant on a semiconductor base material having a second natural lattice constant, said first natural lattice constant being different from said second natural lattice constant;
forming a crystalline cap material on said threshold adjusting semiconductor material, said crystalline cap material having a third natural lattice constant that differs from said first natural lattice constant; and
forming a gate electrode structure on said crystalline cap material, said gate electrode structure comprising a gate insulation layer comprising a high-k dielectric material.

2. The method of claim 1, wherein said third and second natural lattice constants are substantially equal.

3. The method of claim 1, wherein said first natural lattice constant is greater than said second natural lattice constant.

4. The method of claim 3, wherein said third natural lattice constant is less than said second natural lattice constant.

5. The method of claim 1, wherein forming said threshold adjusting semiconductor material comprises depositing a silicon and germanium-containing material.

6. The method of claim 5, wherein forming said crystalline cap material comprises forming a silicon material on said threshold adjusting semiconductor material.

7. The method of claim 5, wherein forming said crystalline cap material comprises forming a silicon and carbon-containing material on said threshold adjusting semiconductor material.

8. The method of claim 5, wherein forming said threshold adjusting semiconductor material comprises incorporating a carbon species when depositing said silicon and germanium-containing material.

9. The method of claim 1, wherein said crystalline cap material is formed with a thickness that is less than a thickness of said threshold adjusting semiconductor material.

10. The method of claim 8, wherein said threshold adjusting semiconductor material is formed with a thickness of approximately 8-12 nm.

11. The method of claim 1, wherein said transistor is a P-channel transistor.

12. The method of claim 1, wherein forming said threshold adjusting semiconductor material and said crystalline cap material comprises performing an epitaxial growth process and changing at least one process parameter of said epitaxial growth process.

13. A method of forming a semiconductor device, the method comprising:
forming a first crystalline semiconductor material on a semiconductor base material of a first active region, while covering a second active region, said first crystalline semiconductor material and said semiconductor base material having different natural lattice constants;
forming a second crystalline semiconductor material on said first crystalline semiconductor material, a natural lattice constant of said second crystalline semiconductor material differing from the natural lattice constant of said first crystalline semiconductor material; and
forming a first gate electrode structure on said second crystalline semiconductor material and a second gate electrode structure on said second active region, said first and second gate electrode structures comprising a gate insulation layer comprising a high-k dielectric material.

14. The method of claim 13, wherein a thickness of said first crystalline semiconductor material is greater than a thickness of said second crystalline semiconductor material.

15. The method of claim 14, wherein the natural lattice constant of said first crystalline semiconductor material is greater than the natural lattice constant of said semiconductor base material.

16. The method of claim 15, wherein the natural lattice constant of said second crystalline semiconductor material is equal to or less than the natural lattice constant of said semiconductor base material.

17. The method of claim 16, wherein said first crystalline semiconductor comprises silicon and germanium.

18. The method of claim 13, wherein said first and second crystalline semiconductor materials are formed in situ.

19. A semiconductor device, comprising:
a drain region and a source region formed in an active region of a transistor;
a channel region formed laterally between said drain region and said source region, said channel region comprising a semiconductor base material, a strain-inducing first semiconductor material formed on said semiconductor base material and a strained second semiconductor material formed on said strain-inducing first semiconductor material; and
a gate electrode structure formed on said strained second semiconductor material, said gate electrode structure comprising a high-k dielectric material, a metal-containing cap layer formed above said high-k dielectric material and a semiconductor electrode material formed above said metal-containing cap layer.

20. The semiconductor device of claim 19, wherein said strained second semiconductor material comprises at least one of silicon and carbon and wherein said first strain-inducing semiconductor material comprises at least silicon and germanium.
